(19) United States
(12) Patent Application Publication
(10) Pub. No.: US 2024/0166832 A1
(43) Pub. Date: May 23, 2024

(54) ARTICLE, DEVICE, OPTICAL DEVICE, AND ARTICLE MANUFACTURING METHOD

(71) Applicant: CANON KABUSHIKI KAISHA, Tokyo (JP)

(72) Inventors: WATARU KIKUCHI, Saitama (JP); HIROKI WAKAYAMA, Kanagawa (JP)

(21) Appl. No.: 18/511,787

(22) Filed: Nov. 16, 2023

(30) Foreign Application Priority Data
Nov. 21, 2022 (JP) 2022-185912

(51) Int. Cl. C08J 7/04; C08J 5/04; G03B 17/12; H05K 5/03

(52) U.S. Cl. CPC C08J 7/042; C08J 5/042; G03B 17/12; H05K 5/03; C08J 2369/00

(57) ABSTRACT

In an article including a carbon fiber crossing layer and a covering film layer, the covering film layer being positioned at an outermost surface, a Uni Direction (UD) layer is disposed between the covering film layer and the carbon fiber crossing layer, and the covering film layer is formed directly on the UD layer.

### BACKGROUND

### Field

The present disclosure relates to an article formed of a laminate including carbon fibers and to a method of manufacturing the article.

### Description of the Related Art

Recently, carbon fiber reinforced plastics have been used as members for which weight saving, high rigidity, and impact resistance are all to be demanded. The carbon fiber reinforced plastics have been used in, for example, casings of office automation devices such as a laptop and a printer, casings of optical devices such as a camera and a lens, mechanical parts, fishing rods, and parts of vehicles such as automobiles and bicycles. In an example, there is employed a molded product using a laminate in which multiple layers including carbon fibers impregnated with resin are laminated, the carbon fibers being lightweight and having high impact resistance.

A carbon fiber molded product including a carbon fiber braided layer is proposed as the above-mentioned molded product using the laminate (see Japanese Patent Laid-Open No. 2012-32745).

### SUMMARY

The present disclosure provides an article including a carbon fiber crossing layer and a covering film layer, the covering film layer being positioned at an outermost surface, wherein a Uni Direction (UD) layer is disposed between the covering film layer and the carbon fiber crossing layer, and the covering film layer is formed directly on the UD layer.

The present disclosure further provides an article including a carbon fiber crossing layer and a covering film layer, the covering film layer being positioned at an outermost surface,
wherein a layer of which linear expansion coefficient is different from a linear expansion coefficient of the carbon fiber crossing layer by 60 PPM/° C. or less is disposed between the covering film layer and the carbon fiber crossing layer.

The present disclosure further provides an article manufacturing method including forming a Uni Direction (UD) layer on a carbon fiber crossing layer and forming a covering film layer on the UD layer, the covering film layer being positioned at an outermost surface.

Further features of the present disclosure will become apparent from the following description of exemplary embodiments with reference to the attached drawings.

### BRIEF DESCRIPTION OF THE DRAWINGS

FIG. 1 is a sectional view illustrating a first embodiment.

FIGS. 2A and 2B are explanatory views illustrating the first embodiment; more specifically, FIG. 2A is a plan view and FIG. 2B is a sectional view.

FIGS. 3A and 3B are explanatory views illustrating the first embodiment; more specifically, FIG. 3A is a plan view and FIG. 3B is a sectional view.

FIG. 4 is an explanatory view illustrating the first embodiment.

FIGS. 5A and 5B are explanatory views illustrating a second embodiment; more specifically, FIG. 5A is a plan view and FIG. 5B is a sectional view.

FIG. 6 is an explanatory view illustrating the second embodiment.

FIG. 7 is an explanatory view illustrating the second embodiment.

FIGS. 8A and 8B are explanatory views illustrating a third embodiment; more specifically, FIG. 8A is a plan view and FIG. 8B is a sectional view.

FIGS. 9A and 9B are explanatory views illustrating an example embodiment; more specifically, FIG. 9A is a plan view and FIG. 9B is a sectional view.

FIGS. 10A and 10B are explanatory views illustrating an example embodiment; more specifically, FIG. 10A is a plan view and FIG. 10B is a sectional view.

### DESCRIPTION OF THE EMBODIMENTS

### First Embodiment

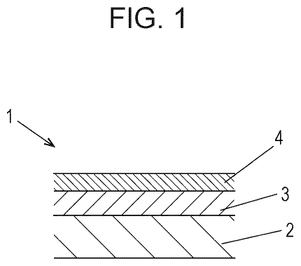

FIG. 1 is a sectional view illustrating a first embodiment that represents an example of the present disclosure.

In FIG. 1, reference numeral 1 denotes an article including a layer in which carbon fibers are crossing each other (namely, a carbon fiber crossing layer), 2 denotes the carbon fiber crossing layer, 3 denotes an underlying layer, and 4 denotes a covering film layer.

The covering film layer 4 for keeping appearance quality is formed at a surface (appearing surface) of the article 1 according to this embodiment. The underlying layer 3 is arranged in contact with a surface of the carbon fiber crossing layer 2 (on a side closer to the appearing surface), and the covering film layer 4 is disposed on the underlying layer 3.

In the carbon fiber crossing layer 2, a difference in level generates due to the crossing of the carbon fibers. According to this embodiment, however, because a UD layer (described later) serving as the underlying layer 3 is arranged on the carbon fiber crossing layer 2, cracks can be suppressed from generating in the covering film layer 4 that is formed above the carbon fiber crossing layer 2. This embodiment represents an example in which the underlying layer 3 is formed directly on the carbon fiber crossing layer 2 and the covering film layer 4 is formed directly on the underlying layer 3. However, the present disclosure is not limited to that example, and it is just required that the underlying layer 3 is formed between the covering film layer 4 and the carbon fiber crossing layer 2. Another layer may be formed between the covering film layer 4 and the underlying layer 3. Alternatively, another layer may be formed between the underlying layer 3 and the carbon fiber crossing layer 2.

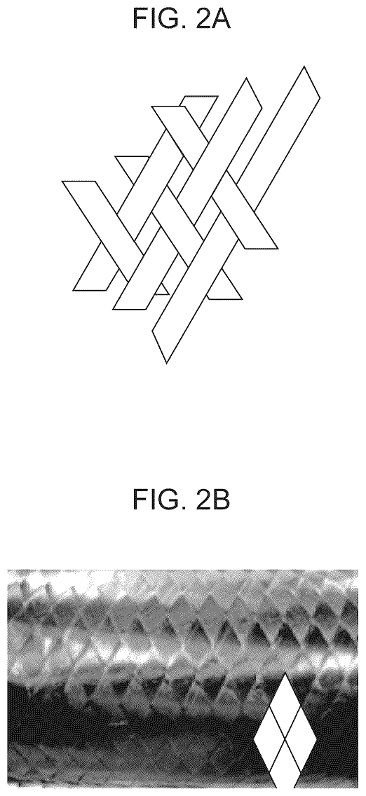

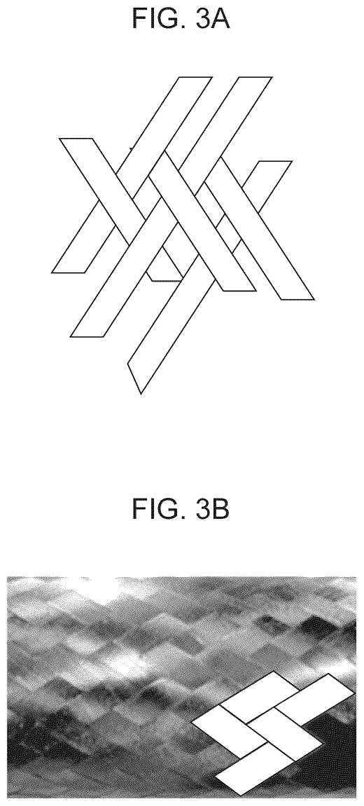

Here, the carbon fiber crossing layer 2 may be a layer formed of a braided material (hereinafter referred to as a “braided layer”) or a layer formed of woven material (hereinafter referred to as a “woven layer”). The braided layer indicates a layer fabricated in such a manner that carbon fibers continuously extending in left and right oblique directions are braided in an up-down direction while crossing each other. FIGS. 2A and 2B are explanatory views of a stone pattern braided layer as an example of the braided material. FIG. 2A illustrates the stone pattern braided layer in a way of representing intervals between the woven carbon fibers to be exaggeratingly increased for easier understanding of a braiding method of stone pattern braiding. FIG. 2B illustrates a portion of a photograph obtained by taking an image of an example of the carbon fiber crossing layer 2 and represents a surface of the carbon fiber crossing layer 2 braided in a stone pattern into a tubular shape. FIGS. 3A and 3B are explanatory views of a twill pattern braided layer as an example of the braided material. FIG. 3A illustrates the twill pattern braided layer in a way of representing intervals between the braided carbon fibers to be exaggeratingly increased for easier understanding of a braiding method of twill pattern braiding. FIG. 3B illustrates a portion of a photograph obtained by taking an image of an example of the carbon fiber crossing layer 2 and represents a surface of the carbon fiber crossing layer 2 braided in a twill pattern into a tubular shape. Although the stone pattern braiding and the twill pattern braiding are described above, the present disclosure is not limited to the stone pattern braiding and the twill pattern braiding when the carbon fiber crossing layer 2 is the braided layer, and any other suitable braiding method may also be used.

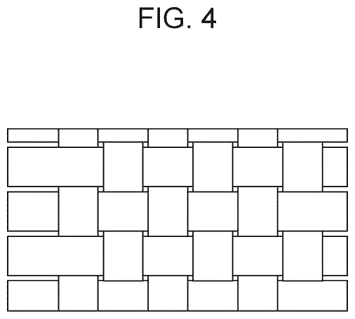

The woven layer indicates a layer fabricated in such a manner that a woven pattern is formed with continuous carbon fibers overlapping each other in vertical and horizontal directions (namely, a manner of forming a fabric usually called in relation to fiber cloth obtained by using a weaving machine). FIG. 4 is an explanatory view of plain weaving as an example of weaving of the fabric and illustrates the plain weaving in a way of representing intervals between the woven carbon fibers to be exaggeratingly increased for easier understanding of a weaving method. When the carbon fiber crossing layer 2 is the woven layer, the weaving method is not limited to the plain weaving and may be twill weaving or another weaving method.

The carbon fibers are preferably impregnated with resin in advance. The resin to be impregnated is not limited to particular one, but Carbon Fiber Reinforced Thermo-Plastics (CFRTP), one of thermoplastic resins, are preferably used. Thus, the type of the resin is not limited to a particular one. As for thermoplastic resins, PA, PC, PMMA, PEEK, PPS, PP, and so on can be used. As for thermosetting resins, epoxy resin, phenol resin, unsaturated polyester resin, vinyl ester resin, and so on can be used.

The carbon fibers may be manufactured, for example, through the steps of sandwiching a continuous fiber sheet material and a resin film between heating rolls or the likes, forming an integrated prepreg sheet, and cutting the prepreg sheet into tapes. As another method, the carbon fibers may be manufactured through the steps of electrostatically attaching resin powder to a continuous fiber sheet material, forming a prepreg sheet by heating the fiber sheet material, and cutting the prepreg sheet into tapes.

Alternatively, yarns each obtained by blending a continuous fiber and a thermoplastic resin yarn may also be used after forming the blended yarns into the shape of a tape. Here, the term “prepreg” indicates the carbon fibers impregnated with the resin in advance.

As another carbon fiber manufacturing method, liquid resin may be coated over continuous fibers.

On that occasion, a sizing agent may be used to increase affinity between the continuous fibers and the resin.

Furthermore, on that occasion, a bundle of the continuous fibers is desirably made open to be flat.

The carbon fiber crossing layer 2 may be a prepreg obtained by impregnating resin into a layer that has been prepared by braiding or weaving the carbon fibers in advance. As an alternative, a prepreg may be obtained by laminating a resin film layer on a layer that has been prepared by braiding or weaving the carbon fibers in advance. Here, a material of the resin to be impregnated or the resin film is not limited to a particular one.

Thus, the type of the resin is not limited to a particular one. As for thermoplastic resins, PA, PC, PMMA, PEEK, PPS, PP, and so on can be used. As for thermosetting resins, epoxy resin, phenol resin, unsaturated polyester resin, vinyl ester resin, and so on can be used.

On that occasion, a sizing agent may be used to increase affinity between the carbon fibers and the resin, and a bundle of the carbon fibers is desirably made open to be flat.

The underlying layer 3 is preferably, for example, a Uni Direction (UD) layer in which the carbon fibers are unidirectionally drawn and arrayed (namely, a layer made of unidirectionally carbon fiber reinforced resin).

When the underlying layer 3 is the UD layer, that layer may be formed of a prepreg obtained by impregnating resin into a layer that has been prepared by unidirectionally drawing and arraying the carbon fibers in advance, or a prepreg obtained by laminating a resin film layer on a layer that has been prepared by unidirectionally drawing and arraying the carbon fibers in advance. The resin to be impregnated is not limited to particular one. As for thermoplastic resins, PA, PC, PMMA, PEEK, PPS, PP, and so on can be used. As for thermosetting resins, epoxy resin, phenol resin, unsaturated polyester resin, vinyl ester resin, and so on can be used. Thus, there are no particular limitations on the type of the resin. However, the resin is more preferably the same as that used to be impregnated into the carbon fiber crossing layer 2. The reason is that using the same resin can increase adhesion between the carbon fiber crossing layer 2 and the underlying layer 3.

A sizing agent may be used to increase affinity between the carbon fibers and the resin, and a bundle of the carbon fibers is desirably made open to be flat.

The resin used here for the impregnation is preferably the same as that used to be impregnated into the continuous carbon fiber crossing layer 2.

Since the continuous carbon fibers of the UD layer are unidirectionally drawn and arrayed, the difference in level caused in the continuous carbon fiber crossing layer 2 can be eliminated due to the arrangement that the level difference is covered with the UD layer including the unidirectional carbon fibers with high elasticity.

Accordingly, the article 1 with good appearance quality can be obtained by forming the covering film layer 4 on the UD layer.

On that occasion, a VF (fiber volume content) is preferably 20% or more.

A difference in linear expansion coefficient between the underlying layer 3 and the carbon fiber crossing layer 2 is preferably 60 PPM/° C. or less. The difference in linear expansion coefficient is more preferably 48 PPM/° C. or less. When the difference in linear expansion coefficient is 60 PPM/° C. or less, the generation of the cracks can be suppressed.

To hold the difference in linear expansion coefficient between the underlying layer 3 and the carbon fiber crossing layer 2 to be 60 PPM/° C. or less, the linear expansion coefficient of the underlying layer 3 is preferably 30 PPM/° C. or less, taking into consideration that the linear expansion coefficient of the carbon fiber crossing layer 2 in the direction of the carbon fibers is about −30 PPM/° C. Thus, when the linear expansion coefficient of the underlying layer 3 is 30 PPM/° C. or less, the generation of the cracks can be suppressed.

Insofar as the difference in linear expansion coefficient between the underlying layer 3 and the carbon fiber crossing layer 2 is 60 PPM/° C. or less, the underlying layer 3 is not limited to the UD layer. In an example, the underlying layer 3 may be a layer including the carbon fibers.

When the underlying layer 3 is the layer including the carbon fibers, the intended effect is obtained just by meeting a condition that the layer includes the carbon fibers, but the content of the carbon fibers is more preferably 20% or more. The layer including the carbon fibers may be obtained, for example, by processing resin in which the carbon fibers are included in advance into a sheet shape by extrusion molding or calender molding. In another example, the layer including the carbon fibers may be obtained by mixing chopped fibers and resin together and by molding the mixture into a sheet shape. The resin to be included in the layer including the carbon fibers is not limited to particular one. As for thermoplastic resins, PA, PC, PMMA, PEEK, PPS, PP, and so on can be used. As for thermosetting resins, epoxy resin, phenol resin, unsaturated polyester resin, vinyl ester resin, and so on can be used. Thus, there are no particular limitations on the type of the resin. However, the resin is more preferably the same as that used to be impregnated into the carbon fiber crossing layer 2. This is because using the same resin can increase adhesion between the carbon fiber crossing layer 2 and the underlying layer 3.

In manufacturing the article 1 according to this embodiment, a laminate of the carbon fiber crossing layer 2 and the underlying layer 3 is first formed.

The laminate may include multiple carbon fiber crossing layers 2 or another UD layer that is different from the UD layer serving as the underlying layer 3 and that is positioned between the carbon fiber crossing layers 2.

While this embodiment illustrates the laminate in the shape of a sheet, the laminate is not limited to the sheet shape. In an example, the laminate may have a tubular shape.

Molded products of various shapes can be each obtained, for example, by placing the above-described laminate in a mold of the desired shape, and by melting and solidifying the resin impregnated to the carbon fibers.

In more detail, first, a sheet becoming the carbon fiber crossing layer 2 is placed in the mold, and a sheet becoming the underlying layer 3 is placed on the former sheet. Then, the mold is closed, and the sheet becoming the carbon fiber crossing layer 2 and the sheet becoming the underlying layer 3 are subjected to impregnation molding together at the same time. By taking out an integrated laminate from the mold after that, a molded product molded following the shape of the mold can be obtained.

On that occasion, the carbon fiber crossing layer 2 and the underlying layer 3 may be directly heated by utilizing, for example, an IR heater or electromagnetic induction heating as a heating unit or manner in the impregnation molding.

Alternatively, after heating the mold by a heater, for example, the continuous carbon fiber crossing layer 2 and the underlying layer 3 may be heated by heat transfer with contact.

In another example, after covering the mold with a film or the like, the mold including the film may be loaded into a furnace and may be heated by heat transfer at an environmental temperature of the furnace. Pressure may be applied, for example, in a manner of pressing the mold, in a manner of covering the mold with a film or the like and then vacuuming the inner side of the film to press the mold with the atmospheric pressure, or in a manner of utilizing pneumatic pressure of an autoclave or the like.

After performing the impregnation molding on the laminate together at the same time, the integrated laminate is released from the mold, and the covering film layer 4 is formed on the underlying layer 3 by a suitable manner of forming the covering film layer, such as painting or coating.

The underlying layer 3 is formed as the UD layer or a layer of which linear expansion coefficient is different from that of the carbon fiber crossing layer 2 by 60 PPM/° C. or less. This enables generation of residual strain to be suppressed, the residual strain being caused due to the difference in linear expansion coefficient during a cooling step after the impregnation molding for integrating the carbon fiber crossing layer 2 and the underlying layer 3.

Thus, by forming the covering film layer 4 on the laminate, the article 1 with good appearance quality can be obtained without causing the cracks.

In forming the covering film layer 4, a surface of the molded product may be smoothed before forming the covering film layer 4. A method of smoothing the surface of the molded product may be, for example, lathe turning, mill turning, cylinder cutting, or film polishing. Thus, there are no particular limitations on the smoothing method. However, an amount to be processed by the smoothing is preferably held at a value smaller than a thickness of the underlying layer 3. In a processing step of the smoothing, the processing may be performed on the molded product that is held on the mandrel 6 without releasing the molded product from the mandrel. As an alternative, after releasing the molded product from the mandrel, the processing may be performed on the molded product set on a jig. Furthermore, the processing is preferably performed while a coolant is applied to the molded product.

A thickness of the covering film layer 4 is desirably 20 μm or more and 200 μm or less. When the thickness is 20 μm or more, the covering film with higher uniformity can be formed on the surface of the molded product. When the thickness is 200 μm or less, man-hours required in a film-forming step to obtain the desired thickness of the covering film reduces, and an increase of the cost can be avoided. Weight saving can also be achieved.

A method of forming the covering film is not limited to a particular one and may be, for example, paining or coating.

A material of the covering film is not limited to a particular one and may be, for example, epoxy resin, urethane resin, fluororesin, polyester resin, silicone resin, acrylic resin, or urethan acrylic resin.

An additive for giving a desired function, such as a pigment or fine particles, may be mixed into the material of the covering film.

The covering film layer 4 may be made up of multiple layers including, for example, a binder layer and a functional layer.

If a reflectance of the covering film layer 4 formed at an outermost surface as in the article 1 according to this embodiment is 3% or more, it would be usual that the cracks are noticeable, and that the appearance quality deteriorates. With the article 1 according to this embodiment, however, even when the reflectance of the covering film layer 4 formed at the outermost surface of the article 1 is 3% or more, the appearance quality can be kept good because the generation of the cracks is suppressed. When the reflectance is 5% or more or 10% or more, the advantageous effect of this embodiment can be developed more preferably or even more preferably. The reflectance in this Specification was measured by using an ultraviolet, visible, and infrared spectrophotometer (made by JASCO Corporation, product name: V-770). A value measured at a light incidence angle of 80 degrees and a wavelength of 550 nm is given as the reflectance.

The article according to this embodiment can be used as, for example, casings of devices such a laptop and a printer, and each of the devices includes parts covered with the casing. The article according to this embodiment can also be used as, for example, casings of optical devices such as a camera and a lens, and each of the optical devices includes parts covered with the casing.

In another example, the casing of the optical device can be used as a structural member for holding an optical element. The article according to this embodiment can be further used in mechanical parts, fishing rods, automobiles, bicycles, rail cars, ships, aircrafts, and so on, including, for example, exterior materials, interior materials, structural materials (such as a body shell, a vehicle body, and an aircraft fuselage), and cushion materials. Among the above-mentioned examples, the automobile parts include automobile exterior materials, automobile interior materials, automobile structural materials, automobile cushion materials, engine room parts, and so on.

Other application examples of the article according to this embodiment include interior materials, exterior materials, and structural materials of buildings, furniture, and so on. In more detail, the article according to this embodiment may be used as, for example, door covering materials, door structural materials, covering materials and structural materials for various types of furniture (such as a desk, a chair, a shelf, and a chest), modular bathrooms, and septic tanks. Still other examples may include a package, a container (such as a tray), a protection member, and a partition member. In addition, the article according to this embodiment may be further used as molded products for casings (housings), structural members, and so on of home appliances (such as a flat screen TV, a refrigerator, a washing machine, a vacuum cleaner, a mobile phone, a handheld game console, and a laptop).

### Second Embodiment

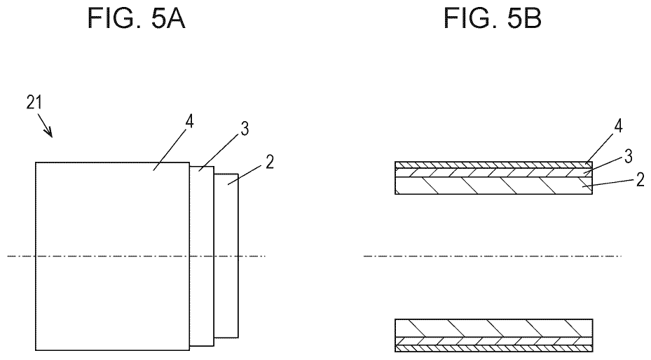

FIGS. 5A and 5B are a plan view and a sectional view, respectively, illustrating a second embodiment of the present disclosure. In this embodiment, a tubular article 21 is described. Components with the same functions as those in the first embodiment are denoted by the same reference numerals, and description of those components is omitted.

In FIGS. 5A and 5B, reference numeral 21 denotes the tubular article including a carbon fiber crossing layer. Reference numeral 2 denotes the carbon fiber crossing layer, 3 denotes the underlying layer, and 4 denotes the covering film layer.

In the article 21 according to this embodiment, as in the first embodiment, the covering film layer 4 is formed at an outermost surface (appearing surface) to maintain the appearance quality. The underlying layer 3 is arranged in contact with a surface of the carbon fiber crossing layer 2 (on a side closer to the appearing surface), and the covering film layer 4 is disposed on the underlying layer 3. When the article has a tubular shape, compressive stress is applied to an innermost surface of the tubular article, and tensile stress is applied to the outermost surface (the appearing surface) thereof. In other words, cracks are hard to generate in the innermost surface while cracks are likely to generate in the outermost surface.

Even in the tubular article in which cracks are likely to generate as described above, when the UD layer serving as the underlying layer 3 is arranged on the carbon fiber crossing layer 2, the cracks can be suppressed from generating in the covering film layer 4 formed on the underlying layer 3. In another case, when a layer of which linear expansion coefficient is different from that of the carbon fiber crossing layer 2 by 60 PPM/° C. or less is arranged on the carbon fiber crossing layer 2, the cracks can be suppressed from generating in the covering film layer 4 formed on the underlying layer 3.

A braider is preferably used to form the carbon fiber crossing layer 2.

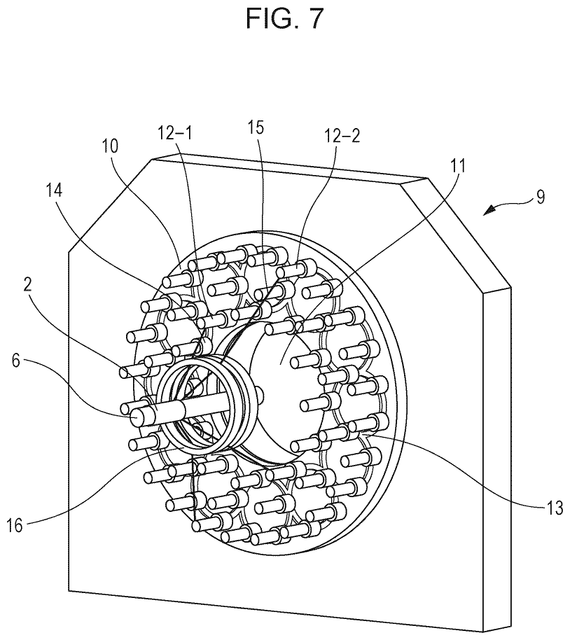

FIG. 7 is a perspective view of the braider.

In FIG. 7, reference numeral 9 denotes the braider, 6 denotes the mandrel, 10 denotes an annular frame, 11 denotes a through-hole, 12-1 and 12-2 denote carriers, 14 and 15 denote the carbon fibers, 13 denotes a figure eight track, 2 denotes the carbon fiber crossing layer, and 16 denotes a guide ring.

The carbon fiber crossing layer 2 in this embodiment is formed over the mandrel 6, also called an arbor, by the braider 9 illustrated in FIG. 7.

The braider 9 includes the annular frame 10, and the mandrel 6 is inserted through the through-hole 11 of the annular frame 10.

The multiple carriers 12-1 and 12-2 for supplying the carbon fibers 14 and 15, respectively, are disposed on the annular frame 10.

Bobbins (not illustrated) are assembled in the carriers 12-1 and 12-2 in a one-to-one relation, and the carbon fibers 14 and 15 are previously wound in the bobbins.

The carbon fibers 14 and 15 previously wound in the bobbins are let out from the carriers 12-1 and 12-2, respectively, and are guided toward the mandrel 6 while the tape-shaped carbon fibers 14 and 15 are each bent by the guide ring 16 toward a direction corresponding to a desired braiding angle.

In this connection, the carriers 12-1 and 12-2 include mechanisms (not illustrated) for generating tension, for example, a spring force, acting on the carbon fibers 14 and 15 to be tightly wound around the mandrel 6.

The carriers 12-1 and 12-2 are moved along the figure eight track 14 formed on the annular frame 10. At that time, a moving direction of the carriers 12-1 which are one half of the total carriers is clockwise, and a moving direction of the carriers 12-2 which are the other half of the total carriers is counterclockwise. Thus, the moving directions of the carriers 12-1 and 12-2 are opposite to each other.

With the above-described movements, the carbon fibers 14 and 15 are caused to cross each other, and the layer 2 made up of the crossing carbon fibers 14 and 15 is formed over the mandrel 6.

On that occasion, supposing that a certain carrier is moved clockwise along the figure eight track, the twill pattern braided layer is obtained by moving the clockwise carrier to pass a crossing point of the figure eight track after passage of two counterclockwise carriers, and the stone pattern braided layer is obtained by moving the clockwise carrier to pass the track crossing point after passage of one counterclockwise carrier.

While the number of the carriers is 48 in FIG. 7, it is not limited to that value.

After that, a sheet serving as the underlying layer 3 is wound over the carbon fiber crossing layer 2.

Then, the impregnation molding is performed.

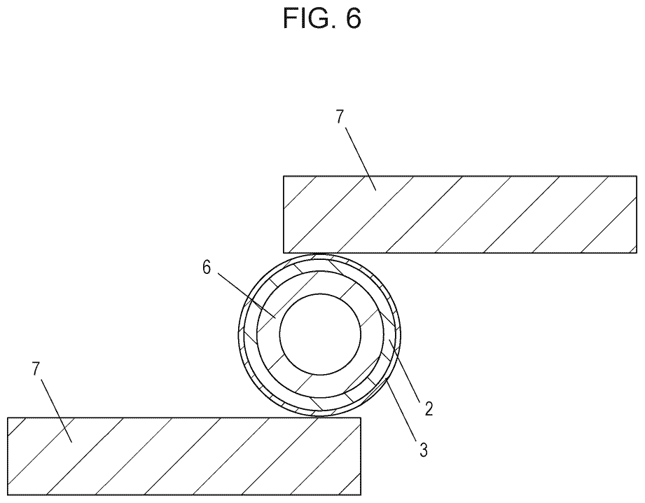

The impregnation molding is performed in a manner of, for example, sandwiching a laminate, which is obtained by laminating the underlying layer 3 on the carbon fiber crossing layer 2 wound around the mandrel 6, between heated molding plates 7 as illustrated in FIG. 6 and by rotating the laminate to swing such that solidification and flow of resin are promoted.

After that, the laminate is cooled and solidified by sandwiching the laminate between the cooled molding plates 7 and by rotating the laminate to swing.

In the above step, when the underlying layer 3 is the UD layer, a fiber direction of the UD layer is preferably aligned with a tube axial direction of the tubular article 21. Here, the term “tube axial direction” indicates a direction in which a tube center line extends. In this Specification, the expression “the fiber direction is aligned with the tube axial direction” is defined as indicating that the fiber direction is in a range of ±15° or less relative to the tube axial direction. When the fiber direction is in a range of ±30° or less relative to the tube axial direction, an effect of suppressing winkles is developed. From the viewpoint of increasing such an effect, the fiber direction is more preferably in the range of ±15° or less relative to the tube axial direction.

When the carbon fiber crossing layer 2 and the UD layer serving as the underlying layer 3 are subjected to the impregnation molding together, they need to be heated to promote the solidification and the flow of the resin. With the heating, because the linear expansion coefficient becomes minus in the fiber direction of the carbon fibers, a force acting to contract the carbon fibers generates. In a subsequent cooling step, a force acting to expand the carbon fibers generates contrary to the above case.

When the fiber direction is not aligned with the tube axial direction and the carbon fibers are wound in a tube circumferential direction, an excess of the carbon fibers generates in the tube circumferential direction during the cooling step due to a force acting to extend the fibers in the fiber direction. Here, the term “tube circumferential direction” indicates a direction along an outer circumference of the tubular article. Because the excess of the carbon fibers is pressed by the cooled molding plates 7 at all times, there is no place for the excessive fibers to escape, thus causing a possibility that the excessive fibers may be finally crushed by the cooled molding plates 7 and wrinkles may generate in the UD layer.

On the other hand, when the fiber direction is aligned with the tube axial direction, an excess of the carbon fibers generates in the tube axial direction during the cooling step due to the force acting to extend the fibers in the fiber direction. However, because the excess of the carbon fibers is movable toward the outside of the cooled molding plates 7 in the tube axial direction even with the fibers pressed by the cooled molding plates 7, wrinkles can be suppressed from generating in the UD layer serving as the underlying layer 3.

Thus, a good external appearance can be obtained by forming the covering film layer 4.

The carbon fiber crossing layer 2 and the underlying layer 3 may be directly heated by utilizing, for example, an IR heater or electromagnetic induction heating as a heating unit or manner in the impregnation molding.

Alternatively, after heating the mandrel 6 by a heater, for example, the carbon fiber crossing layer 2 and the underlying layer 3 may be heated by heat transfer with contact.

In another example, after covering the mandrel 6 with a film or the like, the mandrel 6 including the film may be loaded into a furnace and may be heated by heat transfer at an environmental temperature of the furnace.

Pressure may be applied, for example, in a manner of using the molding plates 7 illustrated in FIG. 6, in a manner of covering the mandrel 6 with a film or the like and then vacuuming the inner side of the film to press the layers on the mandrel 6 with the atmospheric pressure, or in a manner of utilizing pneumatic pressure of an autoclave or the like.

The covering film layer 4 is formed on the underlying layer 3 of the molded product, which has been molded as described above, by a suitable manner of forming the covering film layer, such as painting or coating.

At that time, the molded product may be in a state not released from the mandrel 6 or a state released from the mandrel 6.

In forming the covering film layer 4, a surface of the molded product may be smoothed before forming the covering film layer 4.

A method of smoothing the surface of the molded product may be, for example, lathe turning, mill turning, cylinder cutting, or film polishing. Thus, there are no particular limitations on the smoothing method.

However, an amount to be processed by the smoothing is preferably held at a value smaller than a thickness of the underlying layer 3.

In a processing step of the smoothing, the processing may be performed on the molded product that is held on the mandrel 6 without releasing the molded product from the mandrel. As an alternative, after releasing the molded product from the mandrel, the processing may be performed on the molded product set on a jig.

Furthermore, the processing is preferably performed while a coolant is applied to the molded product.

A thickness of the covering film layer 4 is desirably 20 μm or more and 200 μm or less. When the thickness is 20 μm or more, the covering film with higher uniformity can be formed on the surface of the article 1. When the thickness is 200 μm or less, man-hours required in a film-forming step to obtain the desired thickness of the covering film reduces, and an increase of the cost can be avoided. Weight saving can also be achieved.

A method of forming the covering film is not limited to a particular one and may be, for example, paining or coating.

A material of the covering film is not limited to a particular one and may be, for example, epoxy resin, urethane resin, fluororesin, polyester resin, silicone resin, acrylic resin, or urethan acrylic resin.

An additive for giving a desired function, such as a pigment or fine particles, may be mixed into the material of the covering film.

The covering film layer 4 may be made up of multiple layers including, for example, a binder layer and a functional layer.

The article according to this embodiment preferably has a tubular shape and can be used as, for example, casings of optical devices such as a camera and a lens. Each of the optical devices includes parts covered with the casing. The article according to this embodiment can be further used in mechanical parts, fishing rods, automobiles, bicycles, rail cars, ships, aircrafts, and so on, including, for example, exterior materials, interior materials, structural materials (such as a body shell, a vehicle body, and an aircraft fuselage), and cushion materials. Among the above-mentioned examples, the automobile parts include automobile exterior materials, automobile interior materials, automobile structural materials, automobile cushion materials, engine room parts, and so on.

Other application examples of the article according to this embodiment include interior materials, exterior materials, and structural materials of buildings, furniture, and so on. In more detail, the article according to this embodiment may be used as, for example, door covering materials, door structural materials, covering materials and structural materials for various types of furniture (such as a desk, a chair, a shelf, and a chest), modular bathrooms, and septic tanks. Still other examples may include a package, a container (such as a tray), a protection member, and a partition member. In addition, the article according to this embodiment may be further used as molded products for casings (housings), structural members, and so on of home appliances (such as a flat screen TV, a refrigerator, a washing machine, a vacuum cleaner, a mobile phone, a handheld game console, and a laptop).

### Third Embodiment

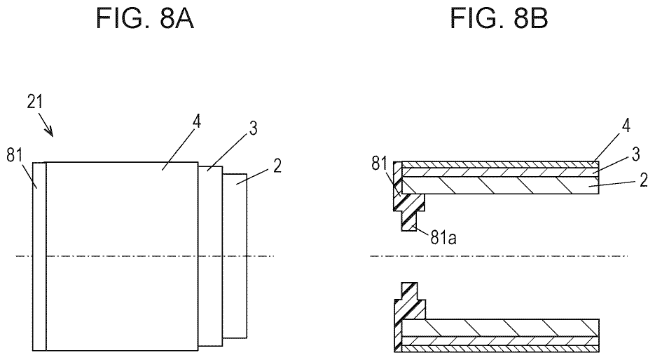

FIGS. 8A and 8B are a plan view and a sectional view, respectively, illustrating a third embodiment of the present disclosure. This embodiment is described in connection with an example in which the tubular article is an optical device. Components with the same functions as those in the first embodiment and the second embodiment are denoted by the same reference numerals, and description of those components is omitted.

The plan view and the sectional view of FIGS. 8A and 8B illustrate a lens barrel component 21 constituting the optical device in this embodiment. The lens barrel component 21 illustrated in FIGS. 8A and 8B is a tubular member forming, for example, a lens barrel component in an optical device such as an interchangeable lens of a camera, the lens barrel component including a lens hood, a focus ring, and a lens barrel structural member, for example, and is constituted as a tubular molded product. Here, the lens hood is a shading component for shielding unwanted light other than shooting light not to enter a shooting optical system and is detachably attached to a fore end of an optical device (image capturing device) such as a camera. Furthermore, other lens barrel components, such as outer and inner tubes of a lens barrel and the focus ring, can be regarded as the lens barrel components that constitute the lens barrel structural members for holding or adjusting optical elements such as a lens and a mirror.

At least one end portion of the lens barrel component 21 is covered with a resin component that is formed as a covering portion 81. The covering portion 81 can be formed by, for example, insert injection molding with thermoplastic resin. In an example, the covering portion 81 is formed to be integrated with the lens barrel component 21 by inserting the lens barrel component 21 into a mold for the injection molding and by performing the injection molding with the thermoplastic resin containing fibers.

For the purpose of, for example, obtaining the sufficient strength when the article is used as a fixing portion or a detachably attached portion of the lens barrel component, the covering portion 81 is preferably made of, for example, the thermoplastic resin containing fibers. The thermoplastic resin forming the covering portion 81 may be, for example, polycarbonate. Using the polycarbonate can provide the lens barrel component in which, for example, the attached portion formed by the covering portion 81 has increased toughness due to high impact resistance of the polycarbonate itself.

By forming the covering portion 81 at the end portion of the lens barrel component 21, it is possible to dispose, on the lens barrel component, a ring component or the like which is to be used as the fixing portion or the detachably attached portion and which cannot be formed in a process of from braiding to solidifying steps in manufacturing of the lens barrel component 21.

In a structure illustrated in FIGS. 8A and 8B, the covering portion 81 is molded to cover the circumference of one end portion of the lens barrel component 21, and a flange 81a circumferentially protruding toward the inner side is formed inside the end portion. When the lens barrel component 21 is the lens barrel structural member, the flange 81a is used as, for example, a support portion for the optical element or the focus ring. When the lens barrel component 21 is, for example, the lens hood that is detachably attached to a main body of the shooting optical system, a resin component formed as the covering portion 81 can be utilized as a portion of a mechanism for detachably attaching the lens hood.

### Examples 1 to 4

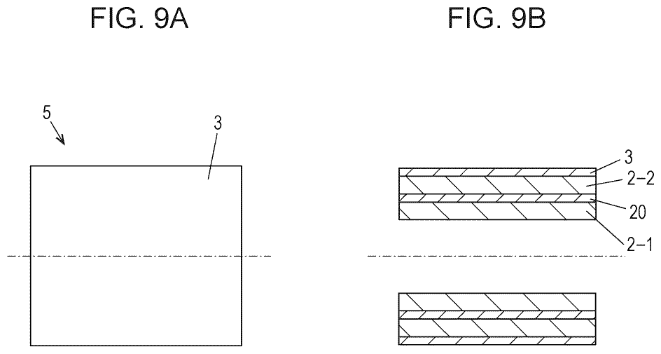

Examples 1 to 4 will be described below with reference to FIGS. 9A and 9B. Components with the same functions as those in the first embodiment or the second embodiment are denoted by the same reference numerals, and description of those components is omitted.

In FIGS. 9A and 9B, reference numeral 5 denotes a tubular article, and 20 denotes a UD layer.

An inner diameter of the article 5 was set to $170.

Two carbon fiber crossing layers 2 (2-1 and 2-2) were formed in the article. The UD layer 20 made up of the carbon fibers arrayed in the tube axial direction was arranged between the two carbon fiber crossing layers 2-1 and 2-2.

After forming one carbon fiber crossing layer 2-1 by braiding, a UD sheet becoming the UD layer 20 was wound around the carbon fiber crossing layer 2-1, and the other carbon fiber crossing layer 2-2 different from the carbon fiber crossing layer 2-1 was formed on the UD sheet by braiding.

On that occasion, tape-shaped carbon fibers (also called carbon fiber reinforced resins) were used in the braiding.

A width of the tape-shaped carbon fibers was 14.5 mm, and a VF (fiber volume content) value thereof was set to 50%. Because of the necessity of giving flexibility to the tape-shaped carbon fibers (carbon fiber reinforced resins) during the braiding, the resin to be impregnated was held in a semi-impregnation state, and a density in the semi-impregnation state was set to fall in a range of 50% to 60%.

The resin to be impregnated was given as PC (polycarbonate) with viscosity average molecular weight of 20000.

The tape-shaped carbon fibers were fabricated by sandwiching a carbon fiber sheet material in an opened flat form and a PC film between heating rolls, for example, by integrating those sheet and film into a prepreg sheet, and by cutting the prepreg sheet into tapes.

Four types of sheets (namely, a sheet containing 10% of carbon fibers, a sheet containing 20% of carbon fibers, a sheet containing 30% of carbon fibers, and a UD sheet), each becoming the underlying layer 3, were prepared, and those sheets were each separately wound over the carbon fiber crossing layer 2-2 after being braided.

As a comparative example, a polycarbonate film was wound over the carbon fiber crossing layer 2-2 after being braided.

The linear expansion coefficient of the carbon fibers in the fiber direction, used in the carbon fiber crossing layers 2 (2-1 and 2-2), was −28 PPM/° C.

The sheet containing 10% of carbon fibers was prepared in advance as a sheet obtained by performing extrusion molding of resin containing 10% of carbon fibers to be formed into a sheet shape. The sheet containing 20% of carbon fibers and the sheet containing 30% of carbon fibers were also prepared by the extrusion molding in a similar manner.

A VF (fiber volume content) value of the UD sheet was set to 50%. Because of the necessity of giving flexibility to the UD sheet during the winding, the resin to be impregnated was held in a semi-impregnation state, and a density in the semi-impregnation state was set to fall in a range of 50% to 60%. The resin to be impregnated at that time was given as PC with viscosity average molecular weight of 20000.

An integral tubular molded product was fabricated by winding the sheet containing 10% of carbon fibers around the carbon fiber crossing layer 2-2 and by performing the impregnation molding. In a similar manner, a tubular molded product was fabricated by winding each of the sheet containing 20% of carbon fibers, the sheet containing 30% of carbon fibers, and the UD sheet.

In the above process, the resin (reinforced with the carbon fibers) was given as Panlite (product name) made by TEIJIN LIMITED. Panlite with the grade B-4110R was used for the sheet containing 10% of carbon fibers, Panlite with the grade B-4120R was used for the sheet containing 20% of carbon fibers, and Panlite with the grade B-4130R was used for the sheet containing 30% of carbon fibers. Panlite with the grade LV2225Y was used as the polycarbonate film containing no carbon fibers in the comparative example.

Then, the tubular molded products were each released from the mandrel 6 and subjected to a surface smoothing process after cutting the molded products into even pieces of a required length.

At that time, the surface smoothing process was performed while the tubular molded product was set on a jig and fixedly supported in place.

The surface smoothing process was performed by film polishing.

Abrasive grains of a film medium used in the above-mentioned process were made of silicon carbide, and the abrasive grains with a grain size of 40 μm were selected in use.

Then, painting was performed on a surface of the tubular molded product to form the covering film layer 4 (not illustrated in FIGS. 9A and 9B).

After forming a primer layer to increase adhesion to the molded product, a covering film to improve the appearance quality was formed on the primer layer by painting. The article was thus manufactured. An overall thickness of the covering film was set to 60 μm.

For each of the articles, Table 1 lists the linear expansion coefficient of the underlying layer 3 and the result of observing the state of cracking after the painting. The article in which the cracking was hardly found was rated as A. The article in which the cracking occurred and an appearance failure was recognized was rated as C. The article in which the cracking was relatively suppressed in comparison with the C-rated article was rated as B.

TABLE 1

| | | | | | Comparative |
|---|---|---|---|---|---|
| | Example 1 | Example 2 | Example 3 | Example 4 | Example |
| Sheet becoming underlying | Sheet | Sheet | Sheet | UD sheet | Polycarbonate |
| layer 3 | containing | containing | containing | | film |
| | 10% of | 20% of | 30% of | | |
| | carbon fibers | carbon fibers | carbon fibers | | |
| Linear expansion coefficient | 30 | 20 | 10 | −28 | 68 |
| [PPM/°]C. | | | | | |
| Difference in linear expansion | 58 | 48 | 38 | 0 | 96 |
| coefficient between carbon | | | | | |
| fiber crossing layer 2 and | | | | | |
| underlying layer 3 [PPM/° C.] | | | | | |
| State of cracking after | B | A | A | A | C |
| painting | | | | | |

As seen from a result of reviews, the cracking was suppressed in the examples.

The linear expansion coefficient was measured by the TMA method. Samples were cut out from the underlying layer and the carbon fiber crossing layer of the manufactured article, and the linear expansion coefficients in the tube axial direction and the tube circumferential direction were measured for each sample. Minimum one of the measured values was taken as the linear expansion coefficient for each direction.

### Examples 5 to 7

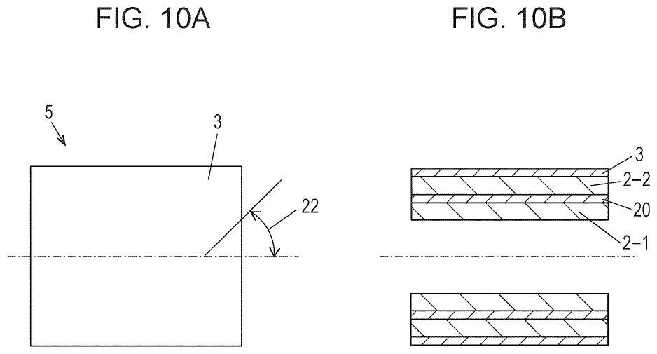

Examples 5 to 7 will be described below with reference to FIGS. 10A and 10B. Components with the same functions as those in the first embodiment, the second embodiment, and examples 1 to 4 are denoted by the same reference numerals, and description of those components is omitted.

In FIGS. 10A and 10B, reference numeral 22 denotes an angle of the carbon fiber direction relative to the tube axial direction.

An inner diameter of a tubular article 5 was set to $170.

Two carbon fiber crossing layers 2 (2-1 and 2-2) were formed in the article. A UD layer 20 in which the fiber direction is aligned with the tube axial direction was arranged between the two carbon fiber crossing layers 2-1 and 2-2.

After forming one carbon fiber crossing layer 2-1 by braiding, a UD sheet becoming the UD layer 20 was wound around the carbon fiber crossing layer 2-1, and the other carbon fiber crossing layer 2-2 was formed on the UD sheet by braiding.

On that occasion, tape-shaped carbon fibers were used in the braiding.

A width of the tape-shaped carbon fibers was 14.5 mm, and a VF (fiber volume content) value thereof was set to 50%. Because of the necessity of giving flexibility to the tape-shaped carbon fibers (carbon fiber reinforced resins) during the braiding, the resin to be impregnated was held in a semi-impregnation state, and a density in the semi-impregnation state was set to fall in a range of 50% to 60%.

The resin to be impregnated was given as PC with viscosity average molecular weight of 20000.

The tape-shaped carbon fibers (carbon fiber reinforced resins) were fabricated by sandwiching a carbon fiber sheet material in an opened flat form and a PC film between heating rolls, for example, by integrating those sheet and film into a prepreg sheet, and by cutting the prepreg sheet into tapes.

In these examples, a UD sheet was used as the sheet becoming the underlying layer 3.

A VF (fiber volume content) value of the UD sheet becoming each of the underlying layer 3 and the UD layer 20 was set to 50%. Because of the necessity of giving flexibility to the UD sheet during the winding, the resin to be impregnated was held in a semi-impregnation state, and a density in the semi-impregnation state was set to fall in a range of 50% to 60%.

The resin to be impregnated was given as PC with viscosity average molecular weight of 20000.

An integrated prepreg sheet was obtained by sandwiching a carbon fiber sheet material in an opened flat form and a PC film between heating rolls, for example.

Then, impregnation molding to obtain a tubular molded product was performed while the UD sheet was arranged such that the angle 22 of the carbon fiber direction relative to the tube axial direction was set to 0°, 15°, and 30°.

As seen from the results listed in Table 2, wrinkles hardly generated when the angle 22 of the carbon fiber direction of the UD sheet becoming the underlying layer 3 relative to the tube axial direction was 0° and 15°. However, the generation of wrinkles was partly found when the angle 22 was 30°.

TABLE 2

| | Example 5 | Example 6 | Example 7 |
|---|---|---|---|
| Angle 22 indicating carbon | 0° | 15° | 30° |
| fiber direction | | | |
| State of wrinkles after | A | A | B |
| impregnation molding | | | |

The tubular molded products were each released from the mandrel and subjected to a surface smoothing process after cutting the molded product into even pieces of a required length.

At that time, the surface smoothing process was performed while the tubular molded product was set on a jig and fixedly supported in place.

The surface smoothing process was performed by film polishing.

Abrasive grains of a film medium used in the above-mentioned process were made of silicon carbide, and the abrasive grains with a grain size of 40 μm were selected in use.

Then, painting was performed on a surface of the tubular molded product to form the covering film layer 4 (not illustrated in FIGS. 10A and 10B).

After forming a primer layer to increase adhesion to the molded product, a covering film to improve the appearance quality was formed on the primer layer. An overall thickness of the covering film was set to 60 μm. The article 5 was thus manufactured.

In analogy with the results obtained for the molded products, it was also confirmed for the manufactured articles 5 that wrinkles hardly generated when the angle 22 of the carbon fiber direction of the UD sheet becoming the underlying layer 3 relative to the tube axial direction was 0° and 15°, and that the generation of wrinkles was partly found when the angle 22 was 30°.

The disclosure in this Specification includes Features 1 to 17 and Method 1 or 2 as follows:

### Feature 1

An article including a carbon fiber crossing layer and a covering film layer, the covering film layer being positioned at an outermost surface, wherein a Uni Direction (UD) layer is disposed between the covering film layer and the carbon fiber crossing layer, and the covering film layer is formed directly on the UD layer.

### Feature 2

The article according to Feature 1, wherein the carbon fiber crossing layer includes resin, and the resin is polycarbonate.

### Feature 3

The article according to Feature 1 or 2, wherein the carbon fiber crossing layer is made of Carbon Fiber Reinforced Thermo-Plastics (CFRTP).

### Feature 4

The article according to any one of Features 1 to 3, wherein the UD layer is formed directly on the carbon fiber crossing layer, and the covering film layer is formed directly on the UD layer.

### Feature 5

The article according to any one of Features 1 to 4, wherein the article has a tubular shape.

### Feature 6

The article according to claim 5, wherein a fiber direction of the UD layer is in a range of ±30° or less relative to a tube axial direction.

### Feature 7

The article according to Feature 5 or 6, wherein the fiber direction is aligned with the tube axial direction.

### Feature 8

The article according to any one of Features 1 to 7, wherein a thickness of the covering film layer is 20 μm or more and 200 μm or less.

### Feature 9

An article including a carbon fiber crossing layer and a covering film layer, the covering film layer being positioned at an outermost surface, wherein a layer of which linear expansion coefficient is different from a linear expansion coefficient of the carbon fiber crossing layer by 60 PPM/° C. or less is disposed between the covering film layer and the carbon fiber crossing layer.

### Feature 10

The article according to Feature 9, wherein the difference in linear expansion coefficient is 48 PPM/° C. or less.

### Feature 11

The article according to claim 9 or 10, wherein the carbon fiber crossing layer includes resin, and the resin is polycarbonate.

### Feature 12

The article according to any one of Features 9 to 11, wherein the carbon fiber crossing layer is made of CFRTP.

### Feature 13

The article according to any one of Features 9 to 12, wherein the layer of which linear expansion coefficient is different from the linear expansion coefficient of the carbon fiber crossing layer by 60 PPM/° C. or less is formed directly on the carbon fiber crossing layer, and the covering film layer is formed directly on the layer of which linear expansion coefficient is different from the linear expansion coefficient of the carbon fiber crossing layer by 60 PPM/° C. or less.

### Feature 14

The article according to any one of Features 9 to 13, wherein the article has a tubular shape.

### Feature 15

The article according to any one of Features 9 to 14, wherein a thickness of the covering film layer is 20 μm or more and 200 μm or less.

### Feature 16

A device including the article according to any one of Features 1 to 15 as a casing, wherein the device includes parts covered with the casing.

### Feature 17

An optical device including an optical element and a structural member arranged to hold the optical element, wherein the optical device includes the article according to any one of Features 1 to 15 as the structural member.

### Method 1

An article manufacturing method, including:
forming a Uni Direction (UD) layer on a carbon fiber crossing layer, and
forming a covering film layer on the UD layer, the covering film layer being positioned at an outermost surface.

### Method 2

The article manufacturing method according to Method 1, wherein the covering film layer is formed after smoothing a surface of the UD layer.

The present disclosure can provide a carbon fiber-containing article in which generation of cracks is suppressed and appearance quality is improved and can further provide a method of manufacturing the article.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-185912, filed Nov. 21, 2022, which is hereby incorporated by reference herein in its entirety.

What is claimed is:

1. An article comprising:
a carbon fiber crossing layer; and
a covering film layer, the covering film layer being positioned at an outermost surface,
wherein a Uni Direction (UD) layer is disposed between the covering film layer and the carbon fiber crossing layer, and
the covering film layer is formed directly on the UD layer.

2. The article according to claim 1, wherein the carbon fiber crossing layer includes resin, and wherein the resin is polycarbonate.

3. The article according to claim 1, wherein the carbon fiber crossing layer is made of Carbon Fiber Reinforced Thermo-Plastics (CFRTP).

4. The article according to claim 1, wherein the UD layer is formed directly on the carbon fiber crossing layer.

5. The article according to claim 1, wherein a surface of the UD layer is flatter than a surface of the carbon fiber crossing layer.

6. The article according to claim 1, wherein the article has a tubular shape.

7. The article according to claim 6, wherein a fiber direction of the UD layer is in a range of ±30° or less relative to a tube axial direction.

8. The article according to claim 7, wherein the fiber direction is aligned with the tube axial direction.

9. The article according to claim 1, wherein a thickness of the covering film layer is 20 μm or more and 200 μm or less.

10. An article comprising:
a carbon fiber crossing layer; and
a covering film layer, the covering film layer being positioned at an outermost surface,
wherein a layer of which linear expansion coefficient is different from a linear expansion coefficient of the carbon fiber crossing layer by 60 PPM/° C. or less is disposed between the covering film layer and the carbon fiber crossing layer.

11. The article according to claim 10, wherein the difference in linear expansion coefficient is 48 PPM/° C. or less.

12. The article according to claim 10, wherein the carbon fiber crossing layer includes resin, and wherein the resin is polycarbonate.

13. The article according to claim 10, wherein the carbon fiber crossing layer is made of CFRTP.

14. The article according to claim 10, wherein the layer of which linear expansion coefficient is different from the linear expansion coefficient of the carbon fiber crossing layer by 60 PPM/° C. or less is formed directly on the carbon fiber crossing layer, and the covering film layer is formed directly on the layer of which linear expansion coefficient is different from the linear expansion coefficient of the carbon fiber crossing layer by 60 PPM/° C. or less.

15. The article according to claim 10, wherein the article has a tubular shape.

16. The article according to claim 10, wherein a thickness of the covering film layer is 20 μm or more and 200 μm or less.

17. A device including the article according to claim 1 as a casing, wherein the device includes parts covered with the casing.

18. An optical device comprising an optical element and a structural member arranged to hold the optical element, wherein the optical device includes the article comprising:
a carbon fiber crossing layer; and
a covering film layer, the covering film layer being positioned at an outermost surface,
wherein a Uni Direction (UD) layer is disposed between the covering film layer and the carbon fiber crossing layer, and
the covering film layer is formed directly on the UD layer as the structural member.

19. An article manufacturing method, comprising:
forming a Uni Direction (UD) layer on a carbon fiber crossing layer, and
forming a covering film layer on the UD layer, the covering film layer being positioned at an outermost surface.

20. The article manufacturing method according to claim 19, wherein the covering film layer is formed after smoothing a surface of the UD layer.
